(19) United States
(12) Patent Application Publication
(10) Pub. No.: US 2026/0251685 A1
(43) Pub. Date: Aug. 27, 2026

(54) VOLTAGE DETECTION DEVICE HAVING TRIMMING RESISTORS AND CAPABLE OF DETERMINING RESISTANCE VALUE OF TRIMMING RESISTORS WITHOUT ADDITIONAL TERMINALS FOR MONITORING INTERNAL CIRCUIT

(71) Applicant: NISSHINBO MICRO DEVICES INC., Tokyo (JP)

(72) Inventors: Tsubasa Sakamoto, Tokyo (JP); Takayasu Yoshikawa, Tokyo (JP); Honoka Hitotsumachi, Tokyo (JP); Shingo Shimizu, Tokyo (JP)

(21) Appl. No.: 19/529,591

(22) Filed: Feb. 4, 2026

(30) Foreign Application Priority Data
Feb. 27, 2025 (JP) 2025-030035

(51) Int. Cl. G01R 19/00; G01R 15/04

(52) U.S. Cl. CPC G01R 19/0038; G01R 15/04

(57) ABSTRACT

First voltage divider resistors are connected between a reference voltage source and a first detection terminal, and have a first intermediate terminal at which a first intermediate voltage between a reference voltage and a first input voltage is produced. A first switch circuit is configured to connect one of the first detection terminal and the first intermediate terminal to a first input terminal of a comparison circuit. Second voltage divider resistors are connected between the reference voltage source and a second detection terminal, and have a second intermediate terminal at which a second intermediate voltage between the reference voltage and a second input voltage is produced. The second voltage divider resistors include trimming resistors having a variable resistance value. A second switch circuit is configured to connect one of the second detection terminal and the second intermediate terminal to a second input terminal of the comparison circuit.

### CROSS REFERENCE TO RELATED APPLICATION

This application claims benefit of priority to Japanese Patent Application 2025-030035, filed Feb. 27, 2025, the entire content of which is incorporated herein by reference.

### BACKGROUND

### Technical Field

The present disclosure relates to a voltage detection device, and also relates to a test device and a test method for the voltage detection device.

### Background Art

A voltage detection device is used to detect a voltage or a current in a circuit. In general, the voltage detection device is provided with voltage divider resistors and a comparator, and compares a voltage at a node in the circuit with a threshold voltage or a voltage at another node in the circuit.

The voltage detection device may have manufacturing variations, such as deviations of resistance values or a resistance ratio of the voltage divider resistors from design values, an offset voltage of a comparator, and the like. In order to reduce an error of a detected voltage due to these variations, for example, trimming resistors are used.

For example, Japanese Patent JP 4740771 B discloses a method for trimming a voltage divider circuit.

### SUMMARY

A voltage detection device is tested to determine a resistance value of trimming resistors during or after manufacturing. The voltage detection device is tested, for example, by monitoring the behavior of an output signal when a known voltage is inputted. In this case, the output signal may include an error from a design value under influences of various factors, such as the deviations of the resistance values or resistance ratio of the voltage divider resistors from design values, and the offset voltage of the comparator, and the like. Since contributions of the respective factor are unknown, it is difficult to accurately determine the resistance value of the trimming resistors based on the output signal including the error. Therefore, it is required to more accurately determine the resistance value of the trimming resistors than the prior art.

In order to accurately determine the resistance value of the trimming resistors, for example, it is possible to monitor behaviors of individual circuit elements of the voltage detection device. However, when the voltage detection device is configured as an integrated circuit, it is necessary to provide the voltage detection device with additional terminals in order to monitor behaviors of individual circuit elements. In this case, there are the additional terminals unnecessary for normal operations of the voltage detection device, which hinders size reduction of the voltage detection device. Therefore, it is required to more accurately determine the resistance value of the trimming resistors than the prior art, without requiring additional terminals for monitoring an internal circuit.

An object of the present disclosure is to provide a voltage detection device provided with trimming resistors, which is capable of more accurately determining a resistance value of the trimming resistors can be than the prior art, without requiring additional terminals for monitoring an internal circuit. Another object of the present disclosure is to provide a test device and a test method for such a voltage detection device.

According to a voltage detection device according to one aspect of the present disclosure, a voltage detection device is provided with: a first detection terminal, a second detection terminal ta reference voltage source, a comparison circuit, first voltage divider resistors, a first switch circuit, second voltage divider resistors, and a second switch circuit. A first input voltage is applied to the first detection terminal. A second input voltage is applied to the second detection terminal. The reference voltage source is configured to produce a predetermined reference voltage. The comparison circuit has first and second input terminals, and is configured to output a signal indicating a higher one of two voltages respectively applied to the first and second input terminals. The first voltage divider resistors connected between the reference voltage source and the first detection terminal, and having a first intermediate terminal at which a first intermediate voltage between the reference voltage and the first input voltage is produced. The first switch circuit configured to connect one of the first detection terminal and the first intermediate terminal to the first input terminal. The second voltage divider resistors connected between the reference voltage source and the second detection terminal, and having a second intermediate terminal at which a second intermediate voltage between the reference voltage and the second input voltage is produced, the second voltage divider resistors including trimming resistors having a variable resistance value. The second switch circuit configured to connect one of the second detection terminal and the second intermediate terminal to the second input terminal.

According to the voltage detection device according to the one aspect of the present disclosure, it is possible to more accurately determine the resistance value of the trimming resistors than the prior art, without requiring additional terminals for monitoring an internal circuit.

### BRIEF DESCRIPTION OF DRAWINGS

FIG. 1 is a diagram illustrating configurations of a voltage detection device 10 and a test device 20 according to a first embodiment;

FIG. 2 is a diagram illustrating an example of trimming resistors Rm of FIG. 1;

FIG. 3 is a diagram illustrating connections of switch circuits 13 and 14 for a case where the voltage detection device 10 of FIG. 1 is operating in a normal mode;

FIG. 4 is a diagram illustrating connections of the switch circuits 13 and 14 for a case where the voltage detection device 10 of FIG. 1 is operating in a resistance ratio mode;

FIG. 5 is a diagram illustrating connections of the switch circuits 13 and 14 for a case where the voltage detection device 10 of FIG. 1 is operating in an offset mode;

FIG. 6 is a flowchart illustrating a test process executed by a controller 21 of FIG. 1;

FIG. 7 is a diagram illustrating configurations of a voltage detection device 10A and the test device 20 according to a second embodiment;

FIG. 8 is a flowchart illustrating a test process executed by the controller 21 of FIG. 7;

FIG. 9 is a diagram illustrating configurations of a voltage detection device 10B and the test device 20 according to a third embodiment;

FIG. 10 is a diagram illustrating configurations of a voltage detection device 10C and the test device 20 according to a fourth embodiment; and

FIG. 11 is a diagram illustrating a configuration of a voltage detection device 10D according to a fifth embodiment.

### DETAILED DESCRIPTION

Hereinafter, embodiments and modifications according to the present disclosure will be described with reference to the drawings. Note that the same or similar components are denoted by the same reference signs.

### First Embodiment

### Configuration of First Embodiment

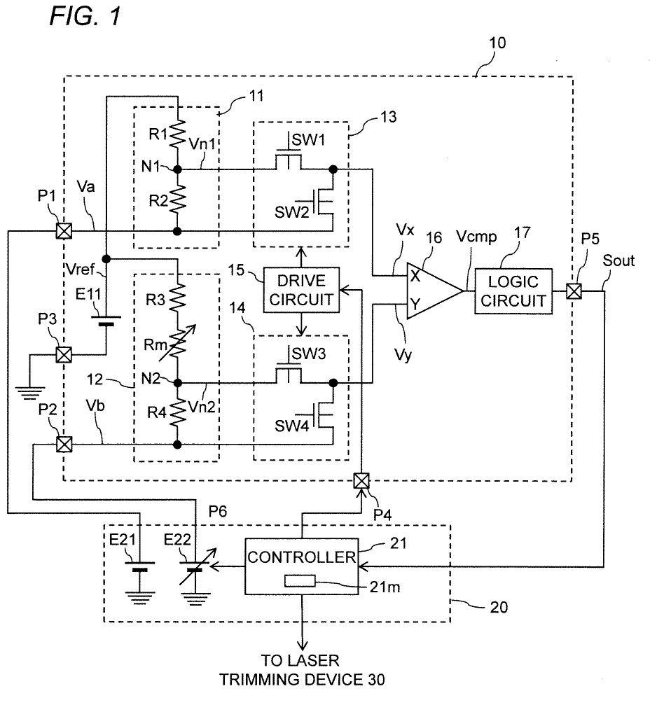

FIG. 1 is a diagram illustrating configurations of a voltage detection device 10 and a test device 20 according to a first embodiment. The voltage detection device 10 compares two input voltages Va and Vb with each other, and when a voltage difference between one input voltage and the other input voltage exceeds a predetermined threshold, the voltage detection device 10 outputs a high-level signal Sout, or otherwise, the voltage detection device 10 outputs a low-level signal Sout. In addition, the voltage detection device 10 is provided with trimming resistors Rm having an adjustable resistance value. The test device 20 determines the resistance value of the trimming resistors Rm, such that the voltage detection device 10 can detect a desired target voltage difference, that is, the transition of the signal Sout between high and low occurs when the two input voltages Va and Vb have the desired target voltage difference, and the test device 20 sets the resistance value to the trimming resistors Rm.

### [Configuration of Voltage Detection Device]

The voltage detection device 10 is provided with a reference voltage source E11, voltage divider resistors 11 and 12, switch circuits 13 and 14, a drive circuit 15, a comparator 16, and a logic circuit 17. In addition, the voltage detection device 10 has terminals P1 to P5.

The input voltage Va is applied to the terminal P1. The input voltage Vb is applied to the terminal P2. The terminals P1 and P2 are also referred to as “detection terminals”.

The reference voltage source E11 produces a predetermined reference voltage Vref. One end of the reference voltage source E11 may be grounded via the terminal P3.

The voltage divider resistors 11 are connected between the reference voltage source E11 and the detection terminal P1. The voltage divider resistors 11 include resistors R1 and R2 connected in series via an intermediate terminal N1, and has a resistance ratio R2/(R1+R2). The resistor R1 is connected between the reference voltage source E11 and the intermediate terminal N1, and the resistor R2 is connected between the detection terminal P1 and the intermediate terminal N1. At the intermediate terminal N1, an intermediate voltage Vn1 between the reference voltage Vref and the input voltage Va, i.e., Vn1=(R2/(R1+R2))×(Vref−Va)+Va, is produced.

The voltage divider resistors 12 are connected between the reference voltage source E11 and the detection terminal P2. The voltage divider resistors 12 include resistors R3, Rm, and R4 connected in series via an intermediate terminal N2, and has a resistance ratio R4/(R3+Rm+R4). The resistors R3 and Rm are connected between the reference voltage source E11 and the intermediate terminal N2, and the resistor R4 is connected between the detection terminal P2 and the intermediate terminal N2. At the intermediate terminal N2, an intermediate voltage Vn2 between the reference voltage Vref and the input voltage Vb, i.e., Vn2=(R4/(R3+Rm+R4))×(Vref−Vb)+Vb, is produced. The resistors Rm are trimming resistors having a variable resistance value. Initially, Rm=0.

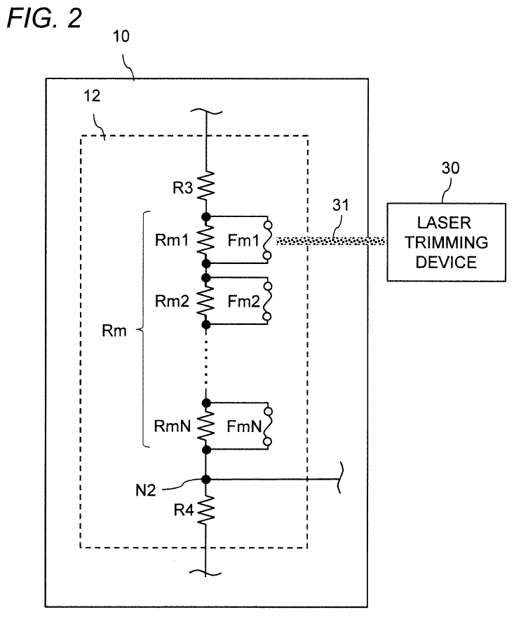

FIG. 2 is a diagram illustrating an example of the trimming resistors Rm of FIG. 1. The trimming resistors Rm include, for example, resistors Rm1 to RmN and fuses Fm1 to FmN. The resistors Rm1 to RmN are connected in series, and each of the fuses Fm1 to FmN is connected in parallel to one corresponding resistor. The fuses Fm1 to FmN may be cut by, for example, laser light 31 produced by a laser trimming device 30. The resistance value of the trimming resistors Rm is adjusted by selectively cutting the fuses Fm1 to FmN according to a resistance value to be set. Initially, each of the fuses Fm1 to FmN is conductive, and the trimming resistors Rm have a resistance value sufficiently smaller than the resistance values of the resistors R3 and R4. In other words, the resistance value of the trimming resistors Rm can be considered to be substantially zero.

Referring to FIG. 1, the switch circuit 13 connects one of the detection terminal P1 and the intermediate terminal N1 to an input terminal X of the comparator 16. The switch circuit 13 is provided with switch elements SW1 and SW2. The switch elements SW1 and SW2 are controlled such that only one of the switch elements SW1 and SW2 is turned on, and the other is turned off. When the switch circuit 13 connects the detection terminal P1 to the input terminal X, the voltage Vx=Va is applied to the input terminal X. When the switch circuit 13 connects the intermediate terminal N1 to the input terminal X, the voltage Vx=Vn1=(R2/(R1+R2))×(Vref−Va)+Va is applied to the input terminal X.

The switch circuit 14 connects one of the detection terminal P2 and the intermediate terminal N2 to an input terminal Y of the comparator 16. The switch circuit 14 is provided with switch elements SW3 and SW4. The switch elements SW3 and SW4 are controlled such that only one of the switch elements SW3 and SW4 is turned on, and the other is turned off. When the switch circuit 14 connects the detection terminal P2 to the input terminal Y, a voltage Vy=Vb is applied to the input terminal Y. When the switch circuit 14 connects the intermediate terminal N2 to the input terminal Y, a voltage Vy=Vn2=(R4/(R3+Rm+R4))×(Vref−Vb)+Vb is applied to the input terminal Y.

The drive circuit 15 is connected to the test device 20 via the terminal P4, and controls connections of the switch circuits 13 and 14 under the control of the test device 20. The drive circuit 15 controls the switch circuits 13 and 14, independently. The voltage detection device 10 has three modes indicating the connections of the switch circuits 13 and 14, i.e., a normal mode, a resistance ratio mode, and an offset mode. The drive circuit 15 controls the connections of the switch circuits 13 and 14 in accordance with a control signal from the test device 20 indicating one of the three modes.

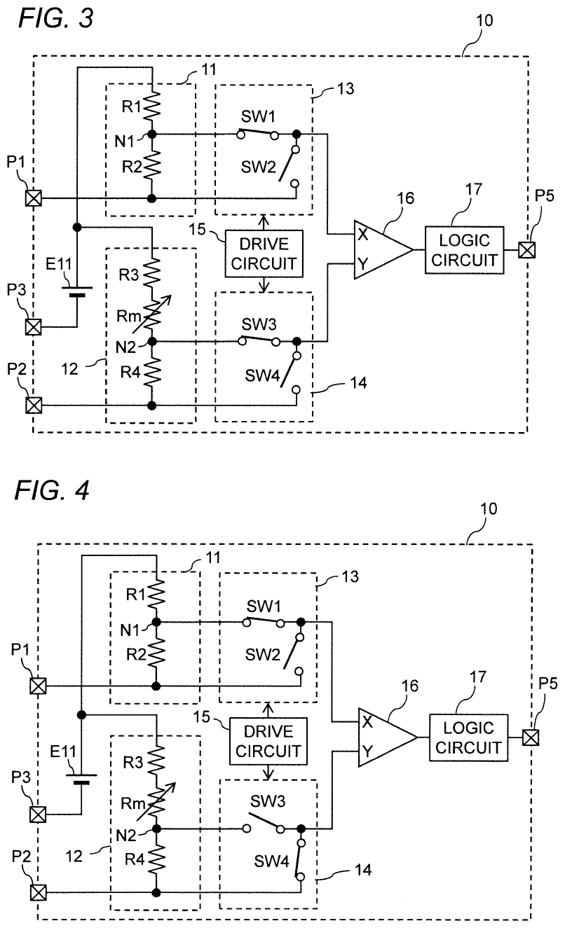

FIG. 3 is a diagram illustrating connections of the switch circuits 13 and 14 for a case where the voltage detection device 10 of FIG. 1 is operating in the normal mode. In the normal mode, the switch circuit 13 connects the intermediate terminal N1 to the input terminal X, and the switch circuit 14 connects the intermediate terminal N2 to the input terminal Y. In this case, the switch element SW1 is turned on, the switch element SW2 is turned off, the switch element SW3 is turned on, and the switch element SW4 is turned off.

FIG. 4 is a diagram illustrating connections of the switch circuits 13 and 14 for a case where the voltage detection device 10 of FIG. 1 is operating in the resistance ratio mode. In the resistance ratio mode, the switch circuit 13 connects the intermediate terminal N1 to the input terminal X, and the switch circuit 14 connects the detection terminal P2 to the input terminal Y. In this case, the switch element SW1 is turned on, the switch element SW2 is turned off, the switch element SW3 is turned off, and the switch element SW4 is turned on.

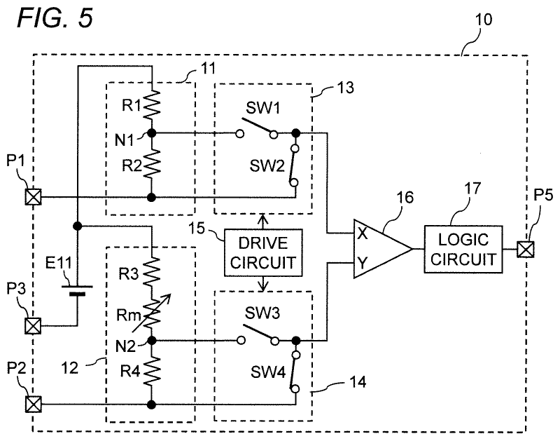

FIG. 5 is a diagram illustrating connections of the switch circuits 13 and 14 for a case where the voltage detection device 10 of FIG. 1 is operating in the offset mode. In the offset mode, the switch circuit 13 connects the detection terminal P1 to the input terminal X, and the switch circuit 14 connects the detection terminal P2 to the input terminal Y. In this case, the switch element SW1 is turned off, the switch element SW2 is turned on, the switch element SW3 is turned off, and the switch element SW4 is turned on.

Referring to FIG. 1, the comparator 16 has the two input terminals X and Y, and the comparator 16 amplifies and outputs a difference between two voltages respectively applied to the input terminals X and Y. The comparator 16 is also called an error amplifier, a differential amplifier, an operational amplifier, or the like. One of the input terminals X and Y is a non-inverting input terminal (+ terminal), and the other is an inverting input terminal (− terminal). The output voltage Vcmp of the comparator 16 is represented by Vcmp=(Vx−Vy)×β for the non-inverting input terminal X, and is represented by Vcmp=(Vy−Vx)×β for the non-inverting input terminal Y, where β is a constant.

When the output voltage Vcmp of the comparator 16 is high, the logic circuit 17 outputs a high-level signal Sout, or otherwise, the logic circuit 17 outputs a low-level signal Sout. As a result, the signal Sout indicates a higher one of the two voltages respectively applied to the input terminals X and Y of the comparator 16. The signal Sout is outputted via the terminal P5.

A set of the comparator 16 and the logic circuit 17 is an example of a comparison circuit.

The voltage detection device 10 may be configured as an integrated circuit.

### [Configuration of Test Device]

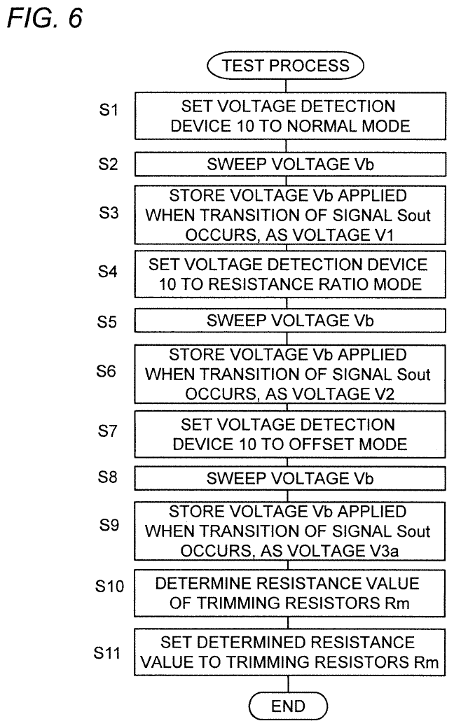

The test device 20 is provided with a reference voltage source E21, a variable voltage source E22, and a controller 21. The reference voltage source E21 produces a predetermined first test voltage, and applies the first test voltage as the input voltage Va to the detection terminal P1. The variable voltage source E22 produces a variable second test voltage under the control of the controller 21, and applies the second test voltage as the voltage Vb to the detection terminal P2. The controller 21 determines and sets the resistance value of the trimming resistors Rm by executing a test process as described later with reference to FIG. 6. In addition, the controller 21 is provided with a memory 21m for storing measured voltages obtained during the test process.

The controller 21 sends a control signal to the drive circuit 15 via the terminal P4 to set the voltage detection device 10 to one of three modes, i.e., the normal mode, the resistance ratio mode, and the offset mode.

In each of the three modes, the controller 21 monitors the signal Sout outputted from the terminal P5 while sweeping the voltage Vb, i.e., while gradually increasing or decreasing the voltage Vb from the initial value. In each of the three modes, the controller 21 obtains, as a measured voltage, the voltage Vb applied when the transition of the signal Sout between high and low (i.e., from low to high, or vice versa) occurs.

The controller 21 determines the resistance value of the trimming resistors Rm based on the measured voltages, and sets the resistance value to the trimming resistors Rm. The controller 21 determines the resistance value of the trimming resistors Rm, such that the transition of the signal Sout between high and low occurs when the input voltages Va and Vb have a predetermined target voltage difference. The controller 21 sets the determined resistance value to the trimming resistors Rm using the laser trimming device 30.

### Operation of First Embodiment

FIG. 6 is a flowchart illustrating a test process executed by the controller 21 of FIG. 1.

The reference voltage source E21 applies the voltage Va to the detection terminal P1. In the initial state before starting the test process, the resistance value of the trimming resistors Rm is substantially zero.

In step S1, the controller 21 sends the control signal to the drive circuit 15 for setting the voltage detection device 10 to the normal mode. In the normal mode, the drive circuit 15 controls the switch circuit 13 to connect the intermediate terminal N1 to the input terminal X, and controls the switch circuit 14 to connect the intermediate terminal N2 to the input terminal Y.

In step S2, the controller 21 monitors the signal Sout while sweeping the voltage Vb.

In step S3, the controller 21 stores the voltage Vb applied when the transition of the signal Sout between high and low occurs, as a measured voltage V1, in the memory 21m. The measured voltage V1 satisfies the following equation.

$$R 2 / ( R 1 + R 2 ) \times ( Vref - Va ) + Va + Vos = R 4 / ( R 3 + R 4 ) \times ( Vref - V 1 ) + V 1 \qquad ( 1 )$$

Here, Vos denotes an offset voltage of the comparator 16.

In step S4, the controller 21 sends the control signal to the drive circuit 15 for setting the voltage detection device 10 to the resistance ratio mode. In the resistance ratio mode, the drive circuit 15 controls the switch circuit 13 to connect the intermediate terminal N1 to the input terminal X, and controls the switch circuit 14 to connect the detection terminal P2 to the input terminal Y.

In step S5, the controller 21 monitors the signal Sout while sweeping the voltage Vb.

In step S6, the controller 21 stores the voltage Vb applied when the transition of the signal Sout between high and low occurs, as a measured voltage V2, in the memory 21m. The measured voltage V2 satisfies the following equation.

$$R 2 / ( R 1 + R 2 ) \times ( Vref - Va ) + Va + Vos = V 2 \qquad ( 2 )$$

In step S7, the controller 21 sends the control signal to the drive circuit 15 for setting the voltage detection device 10 to the offset mode. In the offset mode, the drive circuit 15 controls the switch circuit 13 to connect the detection terminal P1 to the input terminal X, and controls the switch circuit 14 to connect the detection terminal P2 to the input terminal Y.

In step S8, the controller 21 monitors the signal Sout while sweeping the voltage Vb.

In step S9, the controller 21 stores the voltage Vb applied when the transition of the signal Sout between high and low occurs, as a measured voltage V3, in the memory 21m. The measured voltage V3 satisfies the following equation.

$$Vos = V 3 \qquad ( 3 )$$

The measured voltages V1 to V3 may be obtained in a different order. In other words, steps S1 to S3, steps S4 to S6, and steps S7 to S9 may be executed in any order.

In step S10, the controller 21 determines the resistance value of the trimming resistors Rm based on the measured voltages V1 to V3. The voltage Vb applied when the voltages Va and Vb have a desired target voltage difference is represented by Vb=Vt. If the trimming resistors Rm are adjusted such that the voltage detection device 10 detects the target voltage difference, then the resistance value (represented by reference sign Rm) of the trimming resistors Rm satisfies the following equation.

$$R 2 / ( R 1 + R 2 ) \times ( Vref - Va ) + Va + Vos = R 4 / ( R 3 + Rm + R 4 ) \times ( Vref - Vt ) + Vt \qquad ( 4 )$$

As a result, simultaneous equations of Equations (1) to (4) are obtained.

$$R 2 / ( R 1 + R 2 ) \times ( Vref - Va ) + Va + Vos = R 4 / ( R 3 + R 4 ) \times ( Vref - V 1 ) + V 1 \qquad ( 1 )$$

$$R 2 / ( R 1 + R 2 ) \times ( Vref - Va ) + Va + Vos = V 2 \qquad ( 2 )$$

$$Vos = V 3 \qquad ( 3 )$$

$$R 2 / ( R 1 + R 2 ) \times ( Vref - Va ) + Va + Vos = R 4 / ( R 3 + Rm + R 4 ) \times ( Vref - Vt ) + Vt \qquad ( 4 )$$

In Equations (1) to (4), the resistance ratios R2/(R1+R2) and R4/(R3+R4) are unknown because of possible deviations from their design values, and the resistance ratio R4/(R3+Rm+R4) is also unknown. In addition, the offset voltage Vos is also unknown. On the other hand, the voltages Vref, Va, and Vt are known. Therefore, the controller 21 solves Equations (1) to (4) based on the measured voltages V1, V2, and V3 to calculate the resistance ratio R4/(R3+Rm+R4). The controller 21 determines the resistance value of the trimming resistors Rm, such that the voltage divider resistors 12 have the resistance ratio R4/(R3+Rm+R4).

In step S11, the controller 21 sets the determined resistance value to the trimming resistors Rm using the laser trimming device 30.

After setting the determined resistance value to the trimming resistors Rm, the controller 21 may test whether or not the voltage detection device 10 can detect a desired target voltage difference. If there is a significant error, the controller 21 may execute the test process again, and determine and set the resistance value of the trimming resistors Rm so as to reduce the error.

The controller 21 may determine the resistance value of the trimming resistors Rm using two of Equations (1) to (3) and using Equation (4). In this case, the controller 21 sets the voltage detection device 10 to two of the normal mode, the resistance ratio mode, and the offset mode. In each of the two modes, the controller 21 obtains, as measured voltage, the voltage Vb applied when the transition of the signal Sout between high and low occurs. The controller 21 calculates the resistance ratio R4/(R3+Rm+R4) using two of Equations (1) to (3) corresponding to the two measured voltages, and using Equation (4). The controller 21 determines the resistance value Rm of the trimming resistors Rm, such that the voltage divider resistors 12 have the resistance ratio R4/(R3+Rm+R4). As a result, the process can be simplified as compared with the case of setting the voltage detection device 10 to three modes.

As described above, the voltage detection device 10 may be configured as an integrated circuit. In this case, the test device 10 may perform the test process on a voltage detection device 10 on a wafer, and the laser trimming device 30 may set a resistance value to trimming resistors Rm of the voltage detection device 10 on the wafer.

### Advantageous Effects of First Embodiment

According to the first embodiment, the test device 20 sets the voltage detection device 10 to three modes, i.e., the normal mode, the resistance ratio mode, and the offset mode, and obtains the measured voltages V1 to V3 in these modes. The test device 20 can determine the resistance value of the trimming resistors Rm by solving Equations (1) to (4) based on the measured voltages V1 to V3. Since Equations (1) to (4) include the deviations of the resistance ratios of the voltage divider resistors 11 and 12 from their design values, and the offset voltage of the comparator 16, the test device 20 can more accurately determine the resistance value of the trimming resistors Rm than the prior art, in consideration of these factors.

According to the first embodiment, the test device 20 may calculate the deviations of the resistance ratios of the voltage divider resistors 11 and 12 from their design values, and the offset voltage of the comparator 16.

According to the first embodiment, by setting the voltage detection device 10 to three modes and obtaining the measured voltages V1 to V3, the test device 20 can determine the resistance value of the trimming resistors Rm without requiring additional terminals for monitoring an internal circuit of the voltage detection device 10. The test device 20 does not need to directly measure the deviations of the resistance ratios of the voltage divider resistors 11 and 12 from their design value, and the offset voltage of the comparator 16, and therefore, there is no need to provide the voltage detection device 10 with additional terminals for reading these parameters. This makes it possible to prevent an increase in size of the voltage detection device. Furthermore, since no additional terminal is required, it is possible to prevent the voltage detection device 10 from being affected by noise via additional terminals.

As described above, according to the first embodiment, the test device 20 can more accurately determine the resistance value of the trimming resistors Rm than the prior art, without requiring additional terminals for monitoring an internal circuit.

In addition, according to the first embodiment, by setting the voltage detection device 10 to two of the three modes and obtaining two measured voltages, the test device 20 can determine the resistance value of the trimming resistors Rm through a simpler process than the case of obtaining three measured voltages, and with sufficient accuracy.

According to the first embodiment, since the voltage detection device 10 is provided with the switch circuits 13 and 14 and the drive circuit 15, the voltage detection device 10 enables to more accurately determine the resistance value of the trimming resistors Rm than the prior art, without requiring additional terminals for monitoring an internal circuit.

According to the first embodiment, by setting the determined resistance value to the trimming resistors Rm, the voltage detection device 10 can accurately detect the desired target voltage difference.

The voltage detection device 10 may be used, for example, to detect a voltage or a current of the circuit, or to detect overcharge or overdischarge of a secondary battery.

### Second Embodiment

### Configuration of Second Embodiment

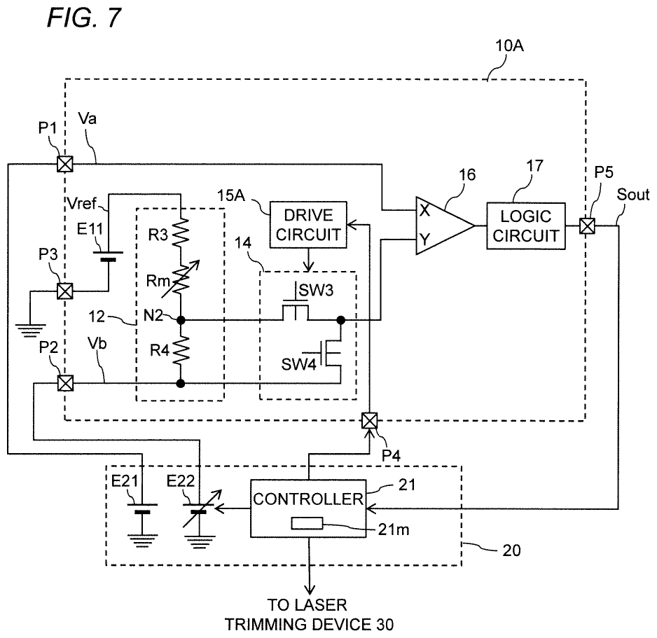

FIG. 7 is a diagram illustrating configurations of a voltage detection device 10A and the test device 20 according to a second embodiment. The voltage detection device 10A is configured without the voltage divider resistors 11 and the switch circuit 13 of FIG. 1, and is provided with a drive circuit 15A instead of the drive circuit 15 of FIG. 1. The drive circuit 15A controls only one switch circuit 14 under the control of the test device 20. The input terminal X of the comparator 16 is directly connected to the detection terminal P1. The voltage Vx=Va is applied to the input terminal X. In other respects, the voltage detection device 10A is configured in a manner similar to that of the voltage detection device 10.

The voltage detection device 10A has two modes indicating connection of the switch circuit 14, i.e., a normal mode and an offset mode. The drive circuit 15A controls the connection of the switch circuit 14 according to a control signal from the test device 20 indicating one of the two modes. In the normal mode, the switch circuit 14 connects the intermediate terminal N2 to the input terminal Y. In the offset mode, the switch circuit 14 connects the detection terminal P2 to the input terminal Y.

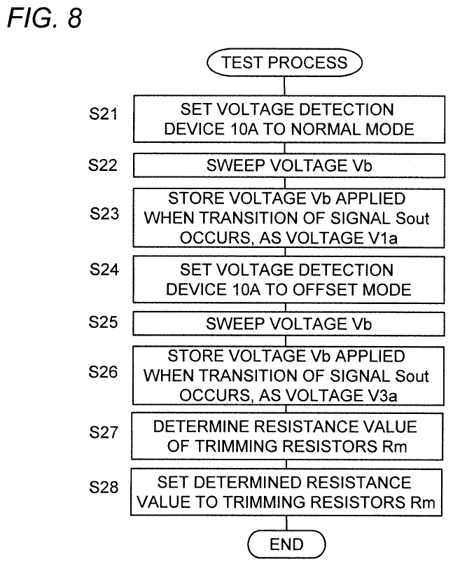

The test device 20 of FIG. 7 is configured in a manner similar to that of the test device 20 of FIG. 1. The controller 21 determines and sets the resistance value of the trimming resistors Rm by executing a test process as described later with reference to FIG. 8.

The controller 21 sets the voltage detection device 10A to one of two modes, i.e., the normal mode and the offset mode.

In each of the two modes, the controller 21 monitors the signal Sout while sweeping the voltage Vb. In each of the two modes, the controller 21 obtains, as a measured voltage, the voltage Vb applied when the transition of the signal Sout between high and low occurs.

The controller 21 determines the resistance value of the trimming resistors Rm based on the measured voltages, and sets the resistance value to the trimming resistors Rm. The controller 21 determines the resistance value of the trimming resistors Rm, such that the transition of the signal Sout between high and low occurs when a voltage difference between the input voltages Va and Vb is equal to a predetermined value. The controller 21 sets the determined resistance value to the trimming resistors Rm using the laser trimming device 30.

### Operation of Second Embodiment

FIG. 8 is a flowchart illustrating a test process executed by the controller 21 of FIG. 7.

The reference voltage source E21 applies the voltage Va to the detection terminal P1. In the initial state before starting the test process, the resistance value of the trimming resistors Rm is substantially zero.

In step S21, the controller 21 sends the control signal to the drive circuit 15A for setting the voltage detection device 10A to the normal mode. In the normal mode, the drive circuit 15A controls the switch circuit 14 to connect the intermediate terminal N2 to the input terminal Y.

In step S22, the controller 21 monitors the signal Sout while sweeping the voltage Vb.

In step S23, the controller 21 stores the voltage Vb applied when the transition of the signal Sout between high and low occurs, as a measured voltage V1a, in the memory 21m. The measured voltage V1a satisfies the following equation.

$$Va + Vos = R 4 / ( R 3 + R 4 ) \times ( Vref - V 1 a ) + V 1 a \qquad ( 1 a )$$

In step S24, the controller 21 sends the control signal to the drive circuit 15A for setting the voltage detection device 10A to the offset mode. In the offset mode, the drive circuit 15A controls the switch circuit 14 to connect the detection terminal P2 to the input terminal Y.

In step S25, the controller 21 monitors the signal Sout while sweeping the voltage Vb.

In step S26, the controller 21 stores the voltage Vb applied when the transition of the signal Sout between high and low occurs, as a measured voltage V3a, in the memory 21m. The measured voltage V3a satisfies the following equation.

$$Vos = V 3 a \qquad ( 3 a )$$

The measured voltages V1a and V3a may be obtained in a different order. In other words, steps S24 to S26 may be executed before steps S21 to S23.

In step S27, the controller 21 determines the resistance value of the trimming resistors Rm based on the measured voltages V1a and V3a. The voltage Vb applied when the voltages Va and Vb have a desired target voltage difference is represented by Vb=Vt. If the trimming resistors Rm are adjusted such that the voltage detection device 10A detects the target voltage difference, then the resistance value (represented by reference sign Rm) of the trimming resistors Rm satisfies the following equation.

$$Va + Vos = R 4 / ( R 3 + Rm + R 4 ) \times ( Vref - Vt ) + Vt \qquad ( 4 a )$$

As a result, simultaneous equations of Equations (1a), (3a), and (4a) are obtained.

$$Va + Vos = R 4 / ( R 3 + R 4 ) \times ( Vref - V 1 a ) + V 1 a \qquad ( 1 a )$$

$$Vos = V 3 a \qquad ( 3 a )$$

$$Va + Vos = R 4 / ( R 3 + Rm + R 4 ) \times ( Vref - Vt ) + Vt \qquad ( 4 a )$$

The controller 21 solves the Equations (1a), (3a), and (4a) based on the measured voltages V1a and V3a to calculate the resistance ratio R4/(R3+Rm+R4). The controller 21 determines the resistance value of the trimming resistors Rm, such that the voltage divider resistors 12 have the resistance ratio R4/(R3+Rm+R4).

In step S28, the controller 21 sets the determined resistance value to the trimming resistors Rm using the laser trimming device 30.

### Advantageous Effects of Second Embodiment

According to the second embodiment, it is possible to achieve the same advantageous effects as those of the first embodiment, even when the input terminal X of the comparator 16 is directly connected to the detection terminal P1.

### Third Embodiment

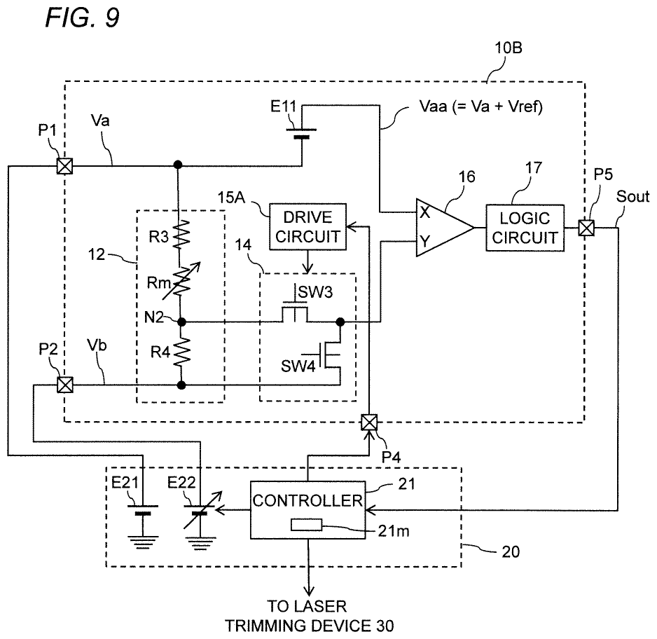

FIG. 9 is a diagram illustrating configurations of a voltage detection device 10B and the test device 20 according to a third embodiment. The voltage detection device 10B is provided with the reference voltage source E11 and the voltage divider resistors 12 at positions different from those of FIG. 7. The reference voltage source E11 is connected between the detection terminal P1 and the input terminal X, produces a predetermined reference voltage Vref, and adds the reference voltage Vref to the input voltage Va. A voltage Vaa=Va+Vref is applied to the input terminal X. The voltage divider resistors 12 is connected between the detection terminals P1 and P2, and has an intermediate terminal N2 at which an intermediate voltage between the input voltages Va and Vb is produced.

Since the input voltage Va and the reference voltage Vref have fixed values, the voltage detection device 10B operates in a manner similar to that of the voltage detection device 10A of FIG. 7, even if the reference voltage source E11 and the voltage divider resistors 12 are provided at different positions.

According to the third embodiment, it is possible to achieve the same advantageous effects as those of the first embodiment, even if the reference voltage source E11 and the voltage divider resistors 12 are provided at different positions.

### Fourth Embodiment

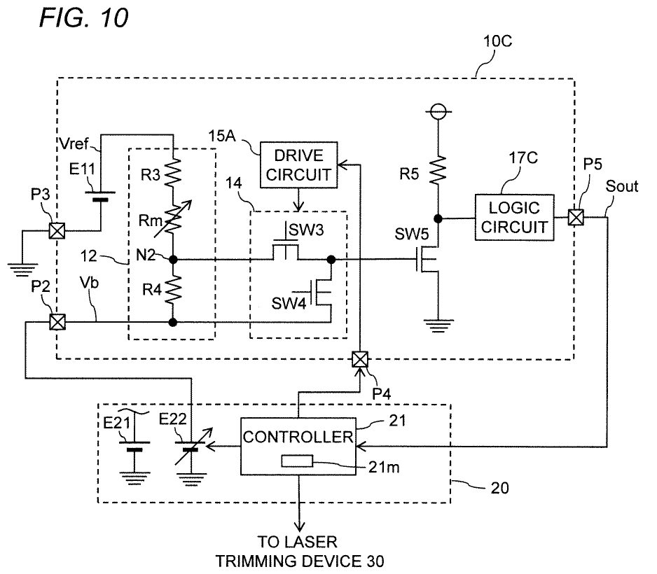

FIG. 10 is a diagram illustrating configurations of a voltage detection device 10C and the test device 20 according to a fourth embodiment. The voltage detection device 10C is provided with a resistor R5, a switch element SW5, and a logic circuit 17C, instead of the comparator 16 and the logic circuit 17 of FIG. 7. In addition, the terminal P1 of FIG. 7 is omitted, and only one input voltage Vb is supplied to the voltage detection device 10C at the terminal P2.

The resistor R5 and the switch element SW5 are connected in series between the power supply and the ground.

The switch element SW5 is, for example, an N-channel MOSFET. The switch circuit 14 connects one of the detection terminal P2 and the intermediate terminal N2 to a control terminal (for example, a gate) of the switch element SW5. When a voltage applied to the control terminal exceeds a predetermined threshold voltage (for example, a gate threshold voltage), the switch element SW5 is turned on, or otherwise, the switch element SW5 is turned off. When the voltage applied to the control terminal exceeds the threshold voltage, a node between the resistor R5 and the switch element SW5 becomes low (for example, a ground voltage), or otherwise, the node becomes high (for example, a power supply voltage).

The switch element SW5 may be regarded as a comparator that compares the voltage applied to the control terminal to a threshold voltage.

The node between the resistor R5 and the switch element SW5 is connected to the logic circuit 17C. When the node between the resistor R5 and the switch element SW5 is low, the logic circuit 17C outputs a high-level signal Sout, or otherwise, the logic circuit 17C outputs a low-level signal Sout. As a result, the signal Sout indicates a higher one of the voltage applied to the control terminal of the switch element SW5 and the threshold voltage of the switch element SW5.

A set of the resistor R5, the switch element SW5, and the logic circuit 17C is an example of a comparison circuit.

The controller 21 determines and sets the resistance value of the trimming resistors Rm by executing a process substantially similar to the test process of FIG. 8. Here, although the input terminal Y of the comparator 16 of FIG. 7 is replaced with the control terminal of the switch element SW5 of FIG. 10, and the voltage Va of FIG. 7 is replaced with the threshold voltage of the switch element SW5 of FIG. 10, the content of the process is substantially similar to that of FIG. 8.

According to the fourth embodiment, it is possible to achieve the same advantageous effects as those described in relation to the first embodiment, even when the resistor R5, the switch element SW5, and the logic circuit 17C are provided instead of the comparator 16 and the logic circuit 17.

### Fifth Embodiment

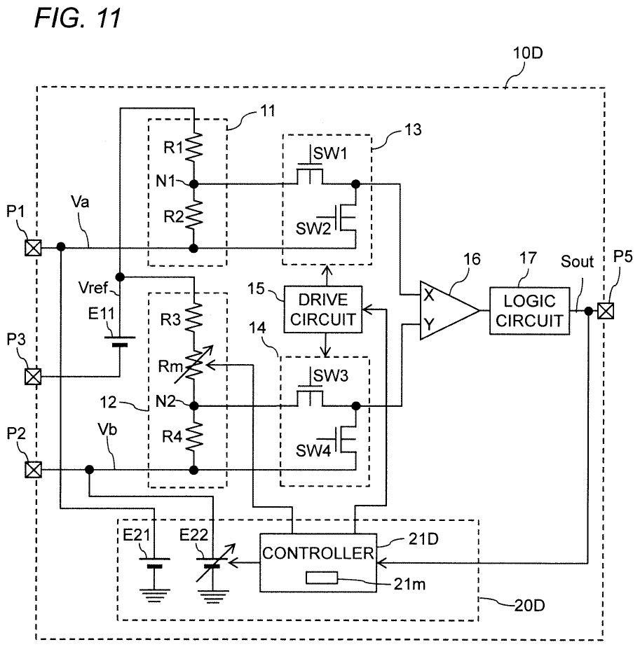

FIG. 11 is a diagram illustrating a configuration of a voltage detection device 10D according to a fifth embodiment. The voltage detection device 10D is provided with a test device 20D integrated therein. The test device 20D may set the resistance value of the trimming resistors Rm by, for example, cutting the fuses Fm1 to FmN of the trimming resistors Rm using a large current. According to the fifth embodiment, the test process can be completed within the voltage detection device 10D.

The voltage detection devices 10A to 10C according to the second to fourth embodiments may also be provided with a test device 20D integrated therein.

### Other Embodiments

Any part or the whole of the voltage divider resistors 11 and 12 may be trimming resistors. The trimming resistors may be connected between the reference voltage source E11 and the intermediate terminal N2, between the detection terminal P1 and the intermediate terminal N1, and/or between the reference voltage source E11 and the intermediate terminal N1.

The trimming resistors are not limited to the configuration illustrated in FIG. 2, and may have any other configuration. The trimming resistors may include, for example, antifuses, fuses cut by current, switches connected in parallel to the resistors, resistors variable depending on temporary or continuous electrical inputs (such as MOSFETs), regulating circuits by logic and transistors, eFUSEs, one time programming (OTP) circuits, electrical trimming circuits, or the like.

A device for setting the trimming resistors, such as a laser trimming device, may be integrated into the test device.

The test device 20 may sweep the voltage Va instead of the voltage Vb.

A bias voltage may be applied externally from the terminal P3. In addition, the reference voltage source E11 may be provided external to the voltage detection device, for example, within the test device 20.

The measured voltage may be stored in the voltage detection device, instead of being stored within the controller 21.

The test device 20 may obtain the voltage difference between the voltages Va and Vb as the measured voltage, instead of obtaining the voltage Vb applied when the transition of the signal Sout between high and low occurs, as the measured voltage.

The terminal P3 may be integrated with one of the detection terminals P1 and P2.

### Summary of Embodiments

According to a first aspect of the present disclosure, a voltage detection device is provided with: a first detection terminal, a second detection terminal ta reference voltage source, a comparison circuit, first voltage divider resistors, a first switch circuit, second voltage divider resistors, and a second switch circuit. A first input voltage is applied to the first detection terminal. A second input voltage is applied to the second detection terminal. The reference voltage source is configured to produce a predetermined reference voltage. The comparison circuit has first and second input terminals, and is configured to output a signal indicating a higher one of two voltages respectively applied to the first and second input terminals. The first voltage divider resistors connected between the reference voltage source and the first detection terminal, and having a first intermediate terminal at which a first intermediate voltage between the reference voltage and the first input voltage is produced. The first switch circuit configured to connect one of the first detection terminal and the first intermediate terminal to the first input terminal. The second voltage divider resistors connected between the reference voltage source and the second detection terminal, and having a second intermediate terminal at which a second intermediate voltage between the reference voltage and the second input voltage is produced, the second voltage divider resistors including trimming resistors having a variable resistance value. The second switch circuit configured to connect one of the second detection terminal and the second intermediate terminal to the second input terminal.

According to a second aspect of the present disclosure, a test device for the voltage detection device of the first aspect is provided. The test device is provided with: a first voltage source, a second voltage source, and a controller. The first voltage source is configured to apply a predetermined first test voltage to the first detection terminal. The second voltage source is configured to apply a variable second test voltage to the second detection terminal. The controller is configured to determine a resistance value of the trimming resistors, and set the resistance value to the trimming resistors. The controller is configured to control connections of the first and second switch circuits according to one of a plurality of modes. The controller is configured to monitor, in each of the plurality of modes, a signal outputted from the comparison circuit while sweeping the second test voltage. The controller is further configured to determine the resistance value of the trimming resistors based on the signal outputted from the comparison circuit, such that a transition of the signal outputted from the comparison circuit occurs when the first and second input voltages have a predetermined target voltage difference, and set the resistance value to the trimming resistors.

According to a third aspect of the present disclosure, the test device of the second aspect is further configured as follows. The plurality of modes includes: a first mode in which the first intermediate terminal is connected to the first input terminal, and the second intermediate terminal is connected to the second input terminal; a second mode in which the first intermediate terminal is connected to the first input terminal, and the second detection terminal is connected to the second input terminal; and a third mode in which the first detection terminal is connected to the first input terminal, and the second detection terminal is connected to the second input terminal. The controller is configured to: obtain, as a measured voltage in each of the first to third modes, the second test voltage applied when the transition of the signal outputted from the comparison circuit occurs; and determine the resistance value of the trimming resistors based on the measured voltages.

According to a fourth aspect of the present disclosure, the test device of the third aspect is further configured as follows. The controller is configured to calculate a resistance ratio R4/(R3+Rm+R4) using Equations (1) to (4):

$$R 2 / ( R 1 + R 2 ) \times ( Vref - Va ) + Va + Vos = R 4 / ( R 3 + R 4 ) \times ( Vref - V 1 ) + V 1 \qquad ( 1 )$$

$$R 2 / ( R 1 + R 2 ) \times ( Vref - Va ) + Va + Vos = V 2 \qquad ( 2 )$$

$$Vos = V 3 \qquad ( 3 )$$

$$R 2 / ( R 1 + R 2 ) \times ( Vref - Va ) + Va + Vos = R 4 / ( R 3 + Rm + R 4 ) \times ( Vref - Vt ) + Vt , \qquad ( 4 )$$

where
R2/(R1+R2) indicates a resistance ratio of the first voltage divider resistors,
R4/(R3+R4) indicates a resistance ratio of the second voltage divider resistors,
Vref indicates the reference voltage,
Va indicates the first test voltage,
Vos indicates an offset voltage of the comparison circuit,
V1 indicates the measured voltage obtained in the first mode,
V2 indicates the measured voltage obtained in the second mode,
V3 indicates the measured voltage obtained in the third mode,
Rm indicates the resistance value of the trimming resistors, and
Vt indicates the second test voltage applied when the first and second test voltages have the target voltage difference.

The controller is configured to determine the resistance value Rm of the trimming resistors, such that the second voltage divider resistors have the resistance ratio R4/(R3+Rm+R4).

According to a fifth aspect of the present disclosure, the test device of the second aspect is further configured as follows. The plurality of modes include two modes among: a first mode in which the first intermediate terminal is connected to the first input terminal, and the second intermediate terminal is connected to the second input terminal; a second mode in which the first intermediate terminal is connected to the first input terminal, and the second detection terminal is connected to the second input terminal; and a third mode in which the first detection terminal is connected to the first input terminal, and the second detection terminal is connected to the second input terminal. The controller is configured to: obtain, as a measured voltage in each of the two modes, the second test voltage applied when the transition of the signal outputted from the comparison circuit occurs; and determine the resistance value of the trimming resistors based on the measured voltages.

According to a sixth aspect of the present disclosure, the test device of the fifth aspect is further configured as follows. The controller is configured to calculate a resistance ratio R4/(R3+Rm+R4) using two of Equations (1) to (3) corresponding to the two modes, and using Equation (4):

$$R 2 / ( R 1 + R 2 ) \times ( Vref - Va ) + Va + Vos = R 4 / ( R 3 + R 4 ) \times ( Vref - V 1 ) + V 1 \qquad ( 1 )$$

$$R 2 / ( R 1 + R 2 ) \times ( Vref - Va ) + Va + Vos = V 2 \qquad ( 2 )$$

$$Vos = V 3 \qquad ( 3 )$$

$$R 2 / ( R 1 + R 2 ) \times ( Vref - Va ) + Va + Vos = R 4 / ( R 3 + Rm + R 4 ) \times ( Vref - Vt ) + Vt , \qquad ( 4 )$$

where
R2/(R1+R2) indicates a resistance ratio of the first voltage divider resistors,
R4/(R3+R4) indicates a resistance ratio of the second voltage divider resistors,
Vref indicates the reference voltage,
Va indicates the first test voltage,
Vos indicates an offset voltage of the comparison circuit,
V1 indicates the measured voltage obtained in the first mode,
V2 indicates the measured voltage obtained in the second mode,
V3 indicates the measured voltage obtained in the third mode,
Rm indicates the resistance value of the trimming resistors, and
Vt indicates the second test voltage applied when the first and second test voltages have the target voltage difference.

The controller is configured to determine the resistance value Rm of the trimming resistors, such that the second voltage divider resistors have the resistance ratio R4/(R3+Rm+R4).

According to a seventh aspect of the present disclosure, a voltage detection device is provided with: a first detection terminal, a second detection terminal ta reference voltage source, a comparison circuit, voltage divider resistors, and a switch circuit. A first input voltage is applied to the first detection terminal. A second input voltage is applied to the second detection terminal. The reference voltage source is configured to produce a predetermined reference voltage. The comparison circuit has first and second input terminals, and is configured to output a signal indicating a higher one of two voltages respectively applied to the first and second input terminals. The first input terminal is connected to the first detection terminal. The voltage divider resistors are connected between the reference voltage source and the second detection terminal, and have an intermediate terminal at which an intermediate voltage between the reference voltage and the second input voltage is produced. The voltage divider resistors include trimming resistors having a variable resistance value. The switch circuit is configured to connect one of the second detection terminal and the intermediate terminal to the second input terminal.

According to a eighth aspect of the present disclosure, a voltage detection device is provided with: a first detection terminal, a second detection terminal ta comparison circuit, a reference voltage source, voltage divider resistors, and a switch circuit. A first input voltage is applied to the first detection terminal. A second input voltage is applied to the second detection terminal. The comparison circuit has first and second input terminals, and is configured to output a signal indicating a higher one of two voltages respectively applied to the first and second input terminals. The reference voltage source is connected between the first detection terminal and the first input terminal, and configured to produce a predetermined reference voltage and adds the reference voltage to the first input voltage. The voltage divider resistors are connected between the first and second detection terminals, and have an intermediate terminal at which an intermediate voltage between the first and second input voltages is produced. The voltage divider resistors include trimming resistors having a variable resistance value. The switch circuit is configured to connect one of the second detection terminal and the intermediate terminal to the second input terminal.

According to a ninth aspect of the present disclosure, a voltage detection device is provided with: a detection terminal, a reference voltage source, a comparison circuit, voltage divider resistors, and a switch circuit. An input voltage is applied to the detection terminal. The reference voltage source is configured to produce a predetermined reference voltage. The comparison circuit has a control terminal, and is configured to output a signal indicating a higher one of a voltage applied to the control terminal and a predetermined threshold voltage. The voltage divider resistors are connected between the reference voltage source and the detection terminal, and have an intermediate terminal at which an intermediate voltage between the reference voltage and the input voltage is produced. The voltage divider resistors include trimming resistors having a variable resistance value. The switch circuit is configured to connect one of the detection terminal and the intermediate terminal to the control terminal.

According to a tenth aspect of the present disclosure, a test method for the voltage detection device of the first aspect is provided. The test method includes applying a predetermined first test voltage to the first detection terminal. The test method includes applying a variable second test voltage to the second detection terminal. The test method includes controlling connections of the first and second switch circuits according to one of a plurality of modes. The test method includes monitoring, in each of the plurality of modes, a signal outputted from the comparison circuit while sweeping the second test voltage. The test method includes determining the resistance value of the trimming resistors based on the signal outputted from the comparison circuit, such that a transition of the signal outputted from the comparison circuit occurs when the first and second input voltages have a predetermined target voltage difference, and setting the resistance value to the trimming resistors.

The voltage detection device according to the aspect of the present disclosure may be used, for example, to detect a voltage or a current of a circuit, or to detect overcharge or overdischarge of a secondary battery.

What is claimed is:

1. A voltage detection device comprising:
a first detection terminal to which a first input voltage is applied;
a second detection terminal to which a second input voltage is applied;
a reference voltage source configured to produce a predetermined reference voltage;
a comparison circuit having first and second input terminals, and configured to output a signal indicating a higher one of two voltages respectively applied to the first and second input terminals;
first voltage divider resistors connected between the reference voltage source and the first detection terminal, and having a first intermediate terminal at which a first intermediate voltage between the reference voltage and the first input voltage is produced;
a first switch circuit configured to connect one of the first detection terminal and the first intermediate terminal to the first input terminal;
second voltage divider resistors connected between the reference voltage source and the second detection terminal, and having a second intermediate terminal at which a second intermediate voltage between the reference voltage and the second input voltage is produced, the second voltage divider resistors including trimming resistors having a variable resistance value; and
a second switch circuit configured to connect one of the second detection terminal and the second intermediate terminal to the second input terminal.

2. A test device for the voltage detection device according to claim 1, the test device comprising:
a first voltage source configured to apply a predetermined first test voltage to the first detection terminal;
a second voltage source configured to apply a variable second test voltage to the second detection terminal; and
a controller configured to determine a resistance value of the trimming resistors, and set the resistance value to the trimming resistors,
wherein the controller is configured to:
control connections of the first and second switch circuits according to one of a plurality of modes;
monitor, in each of the plurality of modes, a signal outputted from the comparison circuit while sweeping the second test voltage; and
determine the resistance value of the trimming resistors based on the signal outputted from the comparison circuit, such that a transition of the signal outputted from the comparison circuit occurs when the first and second input voltages have a predetermined target voltage difference, and set the resistance value to the trimming resistors.

3. The test device according to claim 2,
wherein the plurality of modes includes:
a first mode in which the first intermediate terminal is connected to the first input terminal, and the second intermediate terminal is connected to the second input terminal;
a second mode in which the first intermediate terminal is connected to the first input terminal, and the second detection terminal is connected to the second input terminal; and
a third mode in which the first detection terminal is connected to the first input terminal, and the second detection terminal is connected to the second input terminal, and
wherein the controller is configured to:
obtain, as a measured voltage in each of the first to third modes, the second test voltage applied when the transition of the signal outputted from the comparison circuit occurs; and
determine the resistance value of the trimming resistors based on the measured voltages.

4. The test device according to claim 3,
wherein the controller is configured to calculate a resistance ratio R4/(R3+Rm+R4) using Equations (1) to (4):
$$R 2 / ( R 1 + R 2 ) \times ( Vref - Va ) + Va + Vos = R 4 / ( R 3 + R 4 ) \times ( Vref - V 1 ) + V 1 \qquad ( 1 )$$
$$R 2 / ( R 1 + R 2 ) \times ( Vref - Va ) + Va + Vos = V 2 \qquad ( 2 )$$
$$Vos = V 3 \qquad ( 3 )$$
$$R 2 / ( R 1 + R 2 ) \times ( Vref - Va ) + Va + Vos = R 4 / ( R 3 + Rm + R 4 ) \times ( Vref - Vt ) + Vt , \qquad ( 4 )$$
where
R2/(R1+R2) indicates a resistance ratio of the first voltage divider resistors,
R4/(R3+R4) indicates a resistance ratio of the second voltage divider resistors,
Vref indicates the reference voltage,
Va indicates the first test voltage,
Vos indicates an offset voltage of the comparison circuit,
V1 indicates the measured voltage obtained in the first mode,
V2 indicates the measured voltage obtained in the second mode,
V3 indicates the measured voltage obtained in the third mode,
Rm indicates the resistance value of the trimming resistors, and
Vt indicates the second test voltage applied when the first and second test voltages have the target voltage difference, and
wherein the controller is configured to determine the resistance value Rm of the trimming resistors, such that the second voltage divider resistors have the resistance ratio R4/(R3+Rm+R4).

5. The test device according to claim 2,
wherein the plurality of modes include two modes among:
a first mode in which the first intermediate terminal is connected to the first input terminal, and the second intermediate terminal is connected to the second input terminal;
a second mode in which the first intermediate terminal is connected to the first input terminal, and the second detection terminal is connected to the second input terminal; and
a third mode in which the first detection terminal is connected to the first input terminal, and the second detection terminal is connected to the second input terminal, and
wherein the controller is configured to:
obtain, as a measured voltage in each of the two modes, the second test voltage applied when the transition of the signal outputted from the comparison circuit occurs; and
determine the resistance value of the trimming resistors based on the measured voltages.

6. The test device according to claim 5,
wherein the controller is configured to calculate a resistance ratio R4/(R3+Rm+R4) using two of Equations (1) to (3) corresponding to the two modes, and using Equation (4):
$$R 2 / ( R 1 + R 2 ) \times ( Vref - Va ) + Va + Vos = R 4 / ( R 3 + R 4 ) \times ( Vref - V 1 ) + V 1 \qquad ( 1 )$$
$$R 2 / ( R 1 + R 2 ) \times ( Vref - Va ) + Va + Vos = V 2 \qquad ( 2 )$$
$$Vos = V 3 \qquad ( 3 )$$
$$R 2 / ( R 1 + R 2 ) \times ( Vref - Va ) + Va + Vos = R 4 / ( R 3 + Rm + R 4 ) \times ( Vref - Vt ) + Vt , \qquad ( 4 )$$
where
R2/(R1+R2) indicates a resistance ratio of the first voltage divider resistors,
R4/(R3+R4) indicates a resistance ratio of the second voltage divider resistors,
Vref indicates the reference voltage,
Va indicates the first test voltage,
Vos indicates an offset voltage of the comparison circuit,
V1 indicates the measured voltage obtained in the first mode,
V2 indicates the measured voltage obtained in the second mode,
V3 indicates the measured voltage obtained in the third mode,
Rm indicates the resistance value of the trimming resistors, and
Vt indicates the second test voltage applied when the first and second test voltages have the target voltage difference, and
wherein the controller is configured to determine the resistance value Rm of the trimming resistors, such that the second voltage divider resistors have the resistance ratio R4/(R3+Rm+R4).

7. A voltage detection device comprising:
a first detection terminal to which a first input voltage is applied;
a second detection terminal to which a second input voltage is applied;
a reference voltage source configured to produce a predetermined reference voltage;
a comparison circuit having first and second input terminals, and configured to output a signal indicating a higher one of two voltages respectively applied to the first and second input terminals, the first input terminal being connected to the first detection terminal;
voltage divider resistors connected between the reference voltage source and the second detection terminal, and having an intermediate terminal at which an intermediate voltage between the reference voltage and the second input voltage is produced, the voltage divider resistors including trimming resistors having a variable resistance value; and
a switch circuit configured to connect one of the second detection terminal and the intermediate terminal to the second input terminal.

8. A voltage detection device comprising:
a first detection terminal to which a first input voltage is applied;
a second detection terminal to which a second input voltage is applied;
a comparison circuit having first and second input terminals, and configured to output a signal indicating a higher one of two voltages respectively applied to the first and second input terminals;
a reference voltage source connected between the first detection terminal and the first input terminal, and configured to produce a predetermined reference voltage and adds the reference voltage to the first input voltage;
voltage divider resistors connected between the first and second detection terminals, and having an intermediate terminal at which an intermediate voltage between the first and second input voltages is produced, the voltage divider resistors including trimming resistors having a variable resistance value; and
a switch circuit configured to connect one of the second detection terminal and the intermediate terminal to the second input terminal.

9. A voltage detection device comprising:
a detection terminal to which an input voltage is applied;
a reference voltage source configured to produce a predetermined reference voltage;
a comparison circuit having a control terminal, and configured to output a signal indicating a higher one of a voltage applied to the control terminal and a predetermined threshold voltage;
voltage divider resistors connected between the reference voltage source and the detection terminal, and having an intermediate terminal at which an intermediate voltage between the reference voltage and the input voltage is produced, the voltage divider resistors including trimming resistors having a variable resistance value; and
a switch circuit configured to connect one of the detection terminal and the intermediate terminal to the control terminal.

10. A test method for a voltage detection device,
wherein the voltage detection device comprises:
a first detection terminal to which a first input voltage is applied;
a second detection terminal to which a second input voltage is applied;
a reference voltage source configured to produce a predetermined reference voltage;
a comparison circuit having first and second input terminals, and configured to output a signal indicating a higher one of two voltages respectively applied to the first and second input terminals;
first voltage divider resistors connected between the reference voltage source and the first detection terminal, and having a first intermediate terminal at which a first intermediate voltage between the reference voltage and the first input voltage is produced;
a first switch circuit configured to connect one of the first detection terminal and the first intermediate terminal to the first input terminal;
second voltage divider resistors connected between the reference voltage source and the second detection terminal, and having a second intermediate terminal at which a second intermediate voltage between the reference voltage and the second input voltage is produced, the second voltage divider resistors including trimming resistors having a variable resistance value; and
a second switch circuit configured to connect one of the second detection terminal and the second intermediate terminal to the second input terminal,
wherein the test method includes:
applying a predetermined first test voltage to the first detection terminal;
applying a variable second test voltage to the second detection terminal;
controlling connections of the first and second switch circuits according to one of a plurality of modes;
monitoring, in each of the plurality of modes, a signal outputted from the comparison circuit while sweeping the second test voltage; and
determining the resistance value of the trimming resistors based on the signal outputted from the comparison circuit, such that a transition of the signal outputted from the comparison circuit occurs when the first and second input voltages have a predetermined target voltage difference, and setting the resistance value to the trimming resistors.
